(19) United States
(12) Patent Application Publication
(10) Pub. No.: US 2009/0224266 A1
(43) Pub. Date: Sep. 10, 2009

(54) LED chip package structure applied to a backlight module and method for making the same

(76) Inventors: Bily Wang, Hsinchu City (TW); Shih-Yu Wu, Banciao City (TW); Wen-Kuei Wu, Hukou Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/232,930

(22) Filed: Sep. 26, 2008

(30) Foreign Application Priority Data
Mar. 5, 2008 (TW) 97107706

(51) Int. Cl. H01L 33/00; H01L 21/50

(52) U.S. Cl. 257/88; 438/26; 257/E33.056; 257/E21.499

(57) ABSTRACT

An LED chip package structure applied to a backlight module includes a substrate unit, a light-emitting unit, a package body unit and an opaque unit. The light-emitting unit has a plurality of LED chips electrically arranged on the substrate unit. The package body unit has a plurality of package bodies respectively covering the LED chips. The opaque unit has a plurality of opaque frame bodies formed on the substrate unit, and two opaque frame bodies are respectively formed on two lateral sides of each package body.

### BACKGROUND OF THE INVENTION

1. Field of The Invention

The present invention relates to an LED chip package structure and a method for making the same, and particularly relates to an LED chip package structure applied to a backlight module and a method for making the same.

2. Description of the Related Art

Referring to FIG. 1, a known method for packaging LED chips is shown. The known method includes: providing a plurality of packaged LEDs that have been packaged (S800); providing an elongated substrate body that has a positive trace and a negative trace (S802); and then, arranging each packaged LED on the elongated substrate body in sequence and electrically connecting a positive side and a negative side of each packaged LED with the positive trace and the negative trace of the substrate body (S804).

However, with regard to the known method, each packaged LED needs to be firstly cut from an entire LED package structure, and then each packaged LED is arranged on the elongated substrate body via SMT process. Hence, the known packaging process is time-consuming. Moreover, because the fluorescent bodies are separated from each other, a dark band is easily produced between the two fluorescent bodies and the two LEDs. Hence, the known LED package structure does not offer a good display for users. Moreover, because the package bodies of the packaged LEDs are separated from each other, a dark band is easily produced between two adjacent package bodies and the two packaged LEDs. Hence, the known LED package structure does not offer a good display for users.

### SUMMARY OF THE INVENTION

The present invention provides an LED chip package structure applied to a backlight module and a method for making the same. When the LED chip package structure of the present invention lights up, the LED chip package structure generates a series of light-generating areas on a body unit. Because the series of light-generating areas is continuous, no dark bands are produced between two adjacent LED chips. Furthermore, because the LED chips are arranged on a substrate body via a COB (Chip On Board) method and a hot pressing method, the process for the LED chip package structure is simple and less time is needed for the manufacturing process. Furthermore, the LED chip package structure can be applied to any type of light source such as a back light module, a decorative lamp, a lighting lamp, or a scanner.

A first aspect of the present invention is an LED chip package structure applied to a backlight module, including: a substrate unit, a light-emitting unit, a package body unit and an opaque unit. The light-emitting unit has a plurality of LED chips electrically arranged on the substrate unit. The package body unit has a plurality of package bodies respectively covering the LED chips. The opaque unit has a plurality of opaque frame bodies formed on the substrate unit, and two opaque frame bodies are respectively formed on two lateral sides of each package body.

A second aspect of the present invention is a method for making an LED chip package structure applied to a backlight module, including: providing a substrate unit; electrically arranging a plurality of LED chips on the substrate unit via a matrix method to form a plurality of longitudinal LED chip rows; and longitudinally and respectively covering the longitudinal LED chip rows with a plurality of elongated package bodies.

The method further includes: forming a plurality of elongated opaque frame bodies on the substrate unit, wherein the two elongated opaque frame bodies are respectively formed on two lateral sides of each elongated package body; and transversely cutting the elongated package bodies, the elongated opaque frame bodies and the substrate unit along lines each between adjacent and longitudinal LED chips to form a plurality of light bars, wherein each light bar has a plurality of package bodies that are separated from each other and respectively covering the LED chips and a plurality of opaque frame bodies that are separated from each other and respectively formed on two lateral sides of each package body.

Therefore, because the series of light-generating areas are continuous, no dark bands are produced between two adjacent LED chips. Furthermore, because the LED chips are arranged on the substrate body via a COB (Chip On Board) method and a hot pressing method, the process of the present invention is simple and so reduces the required manufacturing time.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a flowchart of a method for packaging LED chips of the prior art;

FIG. 2 is a flowchart of a method of packaging LED chips package structure according to the first embodiment of the present invention;

FIGS. 2a to 2e are perspective, schematic diagrams of a packaging process according to the first embodiment of the present invention, respectively;

FIGS. 2A to 2E are cross-sectional diagrams of a packaging process according to the first embodiment of the present invention, respectively;

FIG. 3 is a schematic view of LED chips electrically connected on a substrate body via a flip-chip method;

FIG. 4A is a lateral, schematic view of an LED chip package structure applied to a backlight module according to the first embodiment of the present invention;

FIG. 4B is a cross-sectional view of line B-B in FIG. 4A;

FIG. 5 is a flowchart of a method of packaging LED chips package structure according to the second embodiment of the present invention;

FIGS. 5a to 5b are partial, perspective, schematic diagrams of a packaging process according to the second embodiment of the present invention, respectively; and

FIGS. 5A to 5B are partial, cross-sectional diagrams of a packaging process according to the second embodiment of the present invention, respectively.

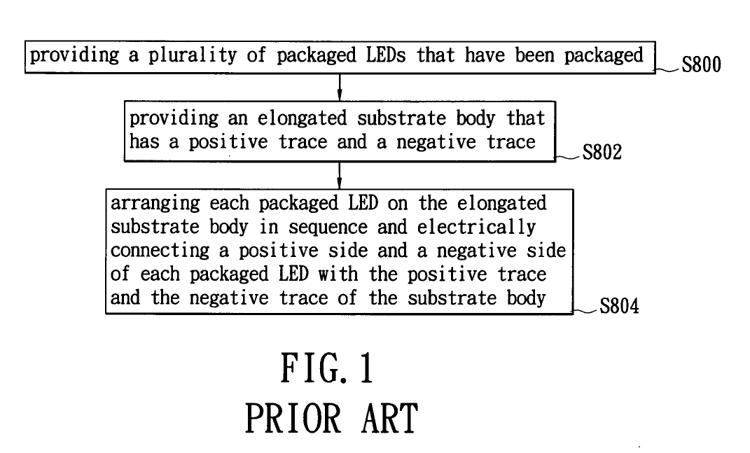

### DETAILED DESCRIPTION OF PREFERRED BEST MOLDS

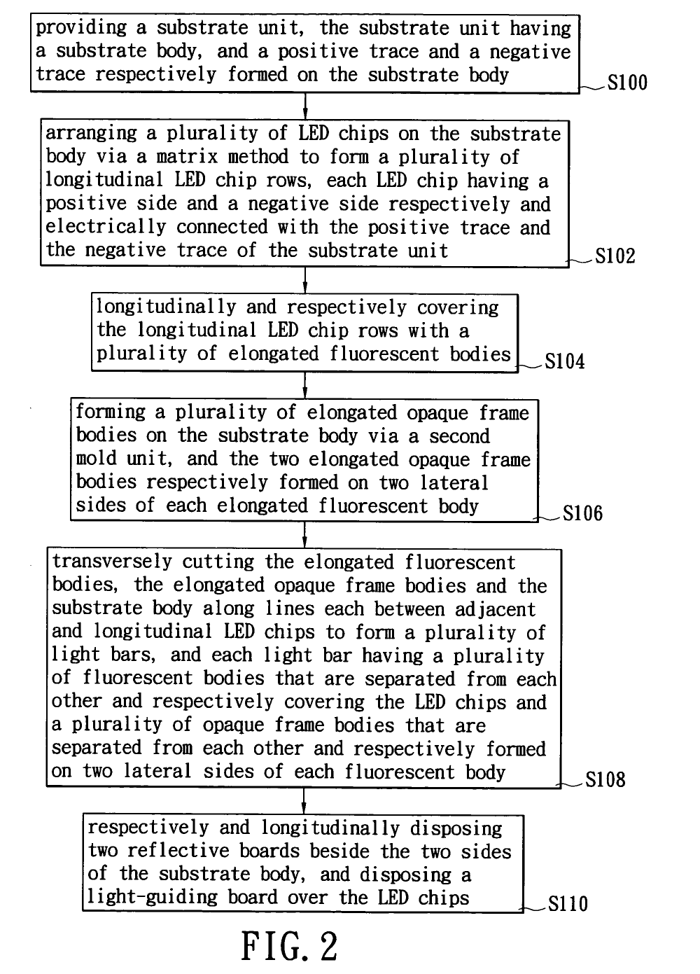

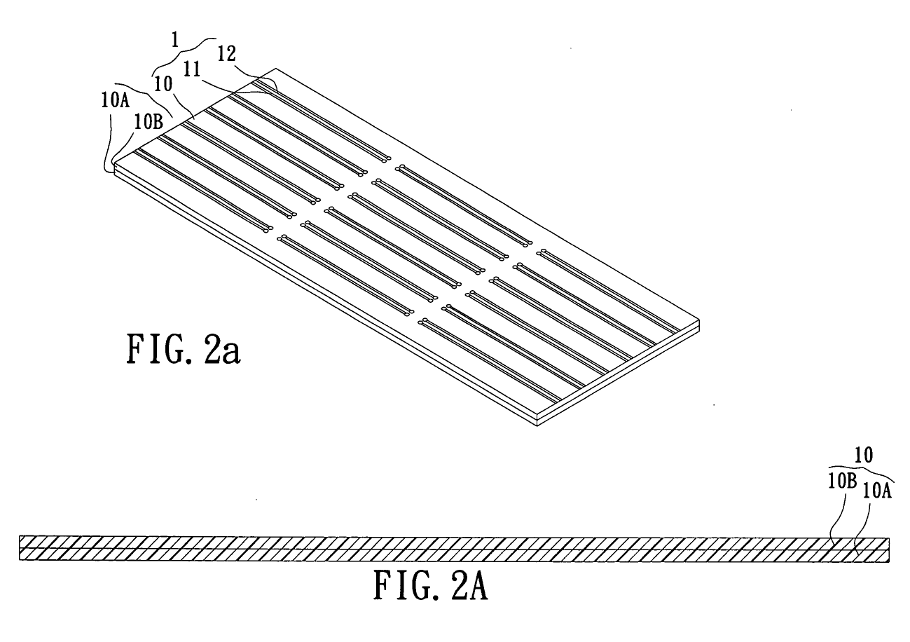

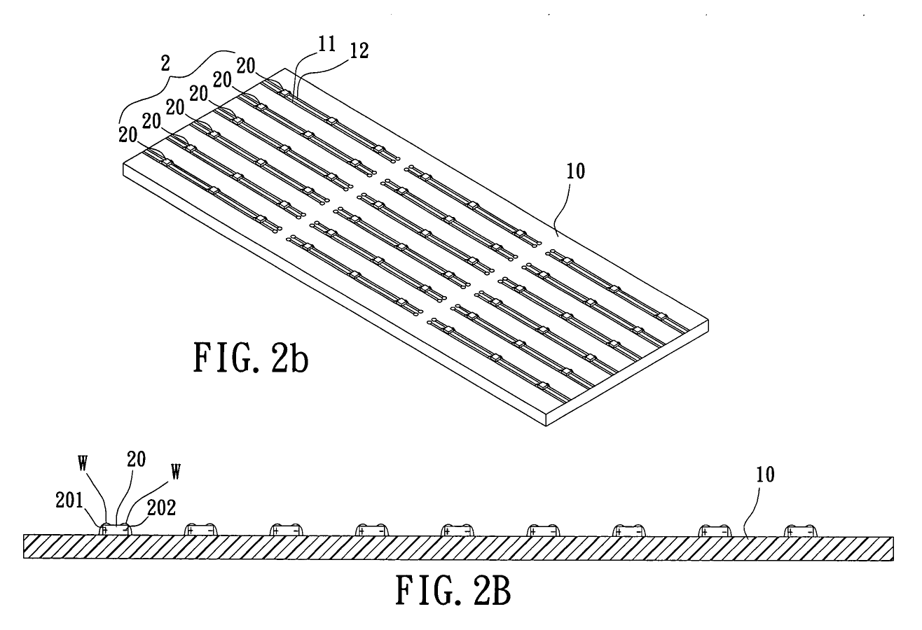

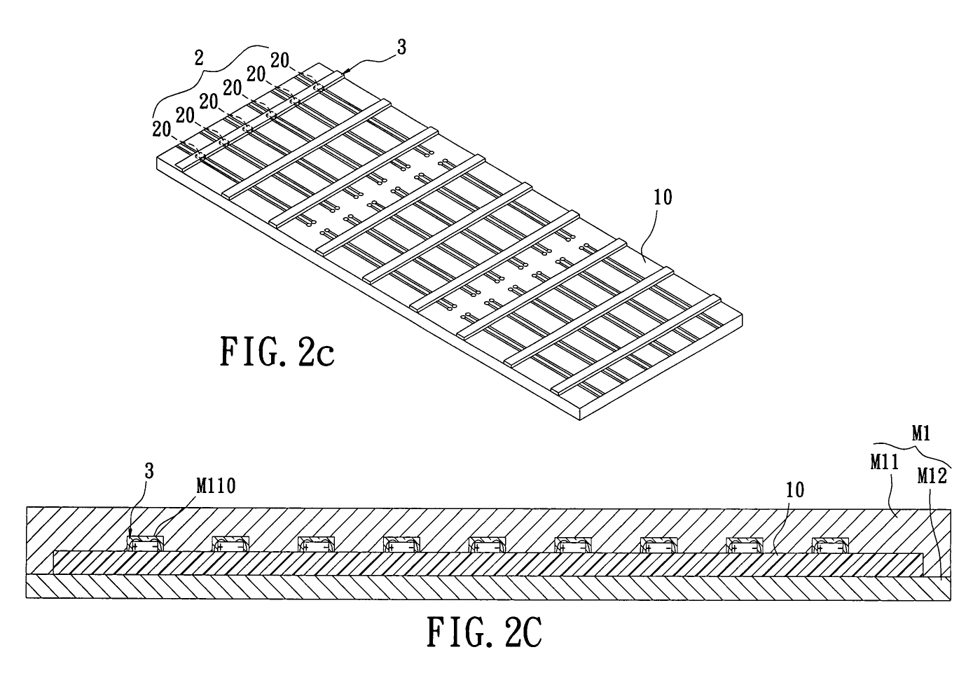

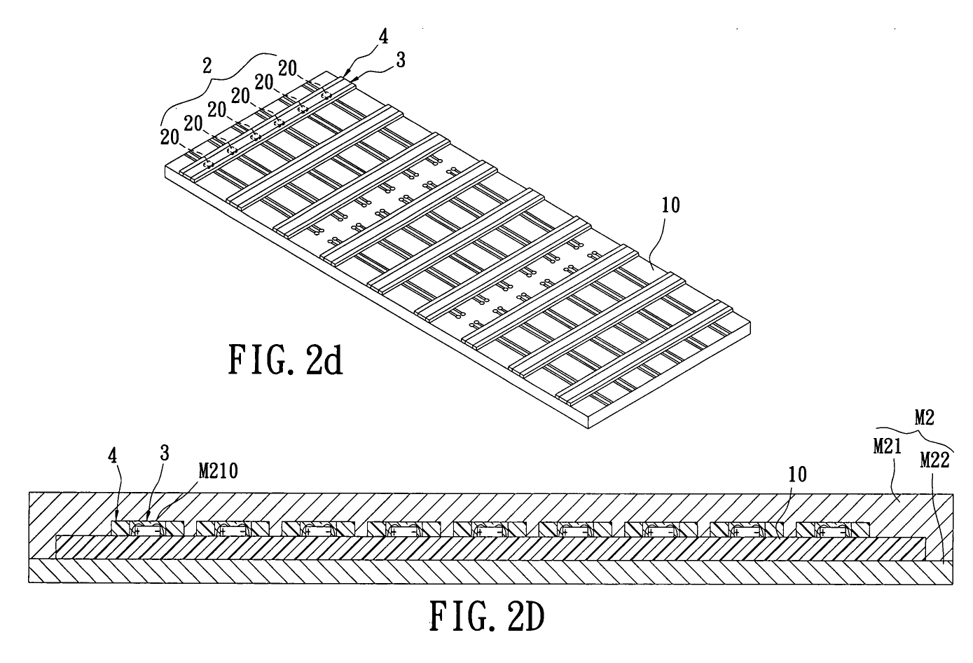

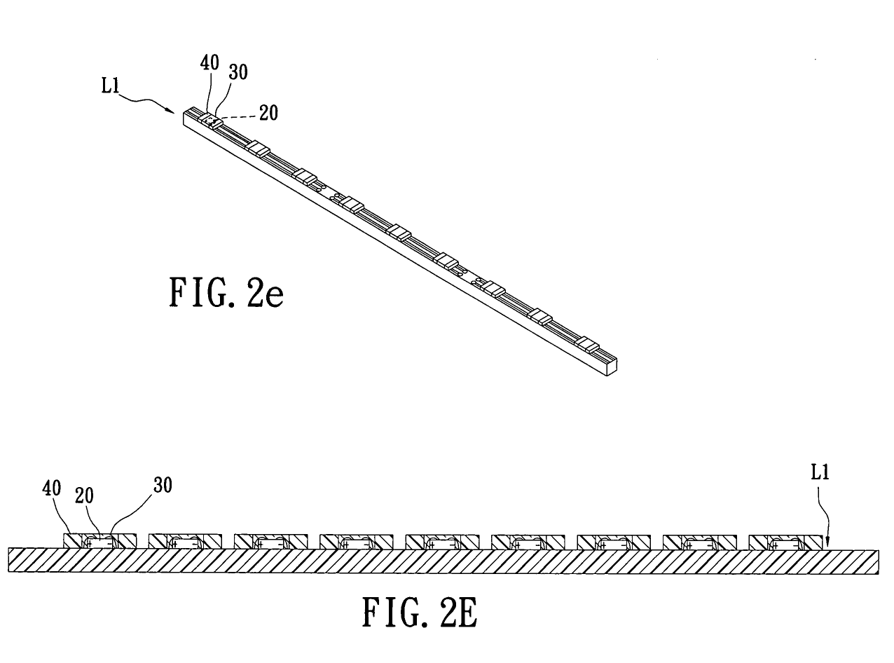

Referring to FIGS. 2, 2a to 2e, and 2A to 2E, the first embodiment of the present invention provides a method for making an LED chip package structure applied to a backlight module. The method includes: referring to FIGS. 2a and 2A, providing a substrate unit 1, the substrate unit having a substrate body 10, and a positive trace 11 and a negative trace 12 respectively formed on the substrate body 10 (S100).

Moreover, the substrate body 10 has a metal layer 10A and a Bakelite layer 10B formed on the metal layer 10A. The substrate unit 1 can be a PCB (Printed Circuit Board), a flexible substrate, an aluminum substrate, a ceramic substrate, or a copper substrate according to different needs. In addition, both the positive trace 11 and the negative trace 12 can be aluminum circuits or silver circuits. The layouts of the positive trace 11 and the negative trace 12 are determined by different needs.

Referring to FIGS. 2b and 2B, the method of the first embodiment further includes: arranging a plurality of LED chips 20 on the substrate body 10 via a matrix method to form a plurality of longitudinal LED chip rows 2, each LED chip 20 having a positive side 201 and a negative side 202 respectively and electrically connected with the positive trace 11 and the negative trace 12 of the substrate unit 1 (S102).

In the first embodiment, the positive side 201 and the negative side 202 of each LED chip 20 are respectively and electrically connected with the positive trace 1 and the negative trace 12 of the substrate unit 1 via two corresponding leading wires W via a wire-bounding method. Moreover, each longitudinal LED chip row 2 is straightly arranged on the substrate body 10 of the substrate unit 1. Each LED chip 20 can be a blue LED chip or an LED chip set for generating white light such as an LED chip set composed of a red LED, a green LED and a blue LED.

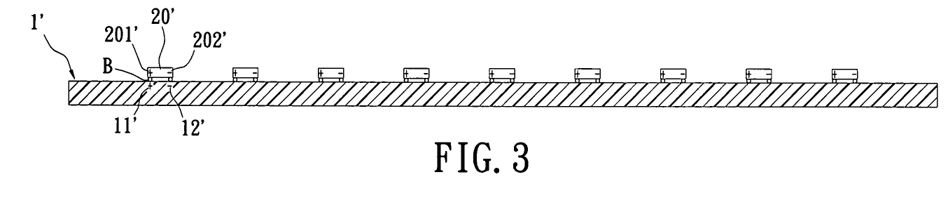

However, the above-mentioned method of electrically connecting the LED chips 20 should not be used to limit the present invention. For example, referring to FIG. 3, the positive side 201′ and the negative side 202′ of each LED chip 20′ respectively and electrically connected with the positive trace 11′ and the negative trace 12′ of the substrate unit 1′ via a plurality of corresponding solder balls B via a flip-chip method. Moreover, according to different needs, positive sides and negative sides of LED chips (not shown) can be electrically connected to a positive trace and a negative trace of a substrate unit (not shown) via parallel, serial, or parallel and serial method.

Referring to FIGS. 2c and 2C, the method of the first embodiment further includes: longitudinally and respectively covering the longitudinal LED chip rows 2 with a plurality of elongated fluorescent bodies 3 (S104). Moreover, the present invention can use a plurality of elongated transparent bodies to replace the elongated fluorescent bodies. If the present invention uses the elongated fluorescent bodies, the LED chips are blue LED chips. If the present invention uses the elongated transparent bodies, the LED chips is an LED chip set for generating white light such as an LED chip set composed of a red LED, a green LED and a blue LED.

Furthermore, the first mold unit M1 is composed of a first upper mold M11 and a first lower mold M12 for supporting the substrate body 10. The first upper mold M11 has a plurality of first channels M110 corresponding to the longitudinal LED chip rows 2.

The height and the width of each first channel M110 are the same as the height and the width of each elongated fluorescent body 3. Moreover, each elongated fluorescent body is a fluorescent resin that is formed by mixing silicon and fluorescent powders or mixing epoxy and fluorescent powders according to different needs.

Finally, referring to FIGS. 2d and 2D, the method of the first embodiment further includes: forming a plurality of elongated opaque frame bodies 4 on the substrate body 10 via a second mold unit M2, and the two elongated opaque frame bodies 4 respectively formed on two lateral sides of each elongated fluorescent body 3 (S106). Moreover, the second mold unit M2 is composed of a second upper mold M21 and a second lower mold M22 for supporting the substrate body 10. The second upper mold M21 has a plurality of second channels M210 corresponding to the elongated opaque frame bodies 4, and the height of each second channel M210 is the same as the height of each elongated fluorescent body 3.

Finally, referring to FIGS. 2d, 2e, and 2E, the method of the second embodiment further includes: transversely cutting the elongated fluorescent bodies 3, the elongated opaque frame bodies 4 and the substrate body 10 along lines each between adjacent and longitudinal LED chips 20 to form a plurality of light bars L1, and each light bar L1 having a plurality of fluorescent bodies 30 that are separated from each other and respectively covering the LED chips 20 and a plurality of opaque frame bodies 40 that are separated from each other and respectively formed on two lateral sides of each fluorescent body 30 (S108). Moreover, the longitudinal width of each fluorescent body 30 and each opaque frame body 40 is below 0.3 mm, such as between 0.01 mm and 0.3 mm.

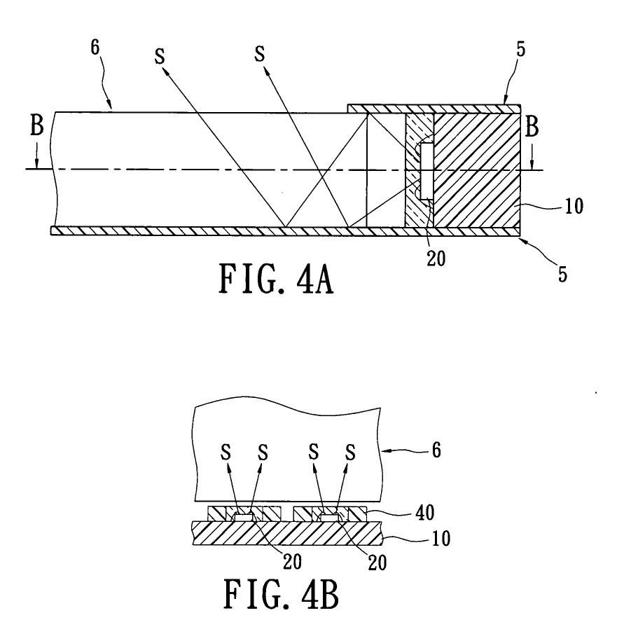

Referring to FIGS. 4A and 4B, the first embodiment of the present invention further includes: respectively and longitudinally disposing two reflective boards 5 beside the two sides of the substrate body 10, and disposing a light-guiding board 6 over the LED chips 20 (S110). Hence, light beams S generated by the LED chips 20 are guided along a predetermined direction by mating the two reflective boards 5 and the opaque frame bodies 40. In addition, the light-guiding board 6 is used to receive the light beams S that have been guided by mating the two reflective boards 5 and the opaque frame bodies 40.

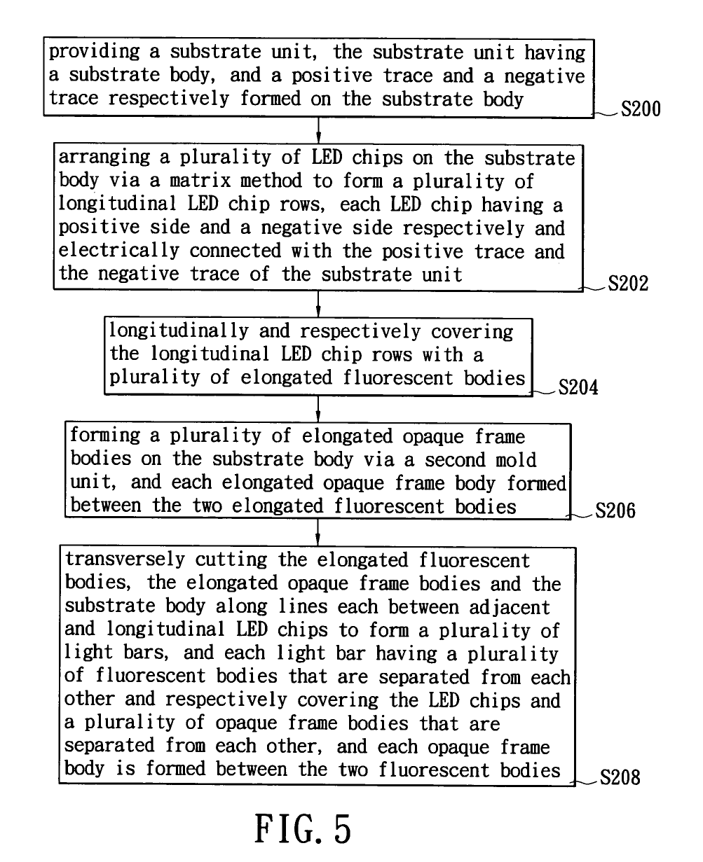

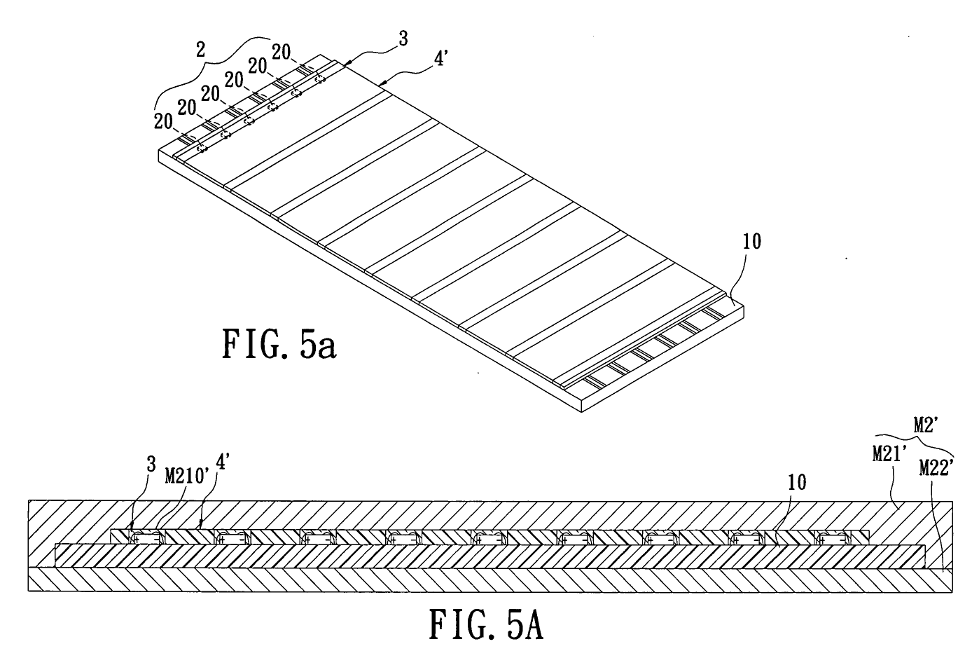

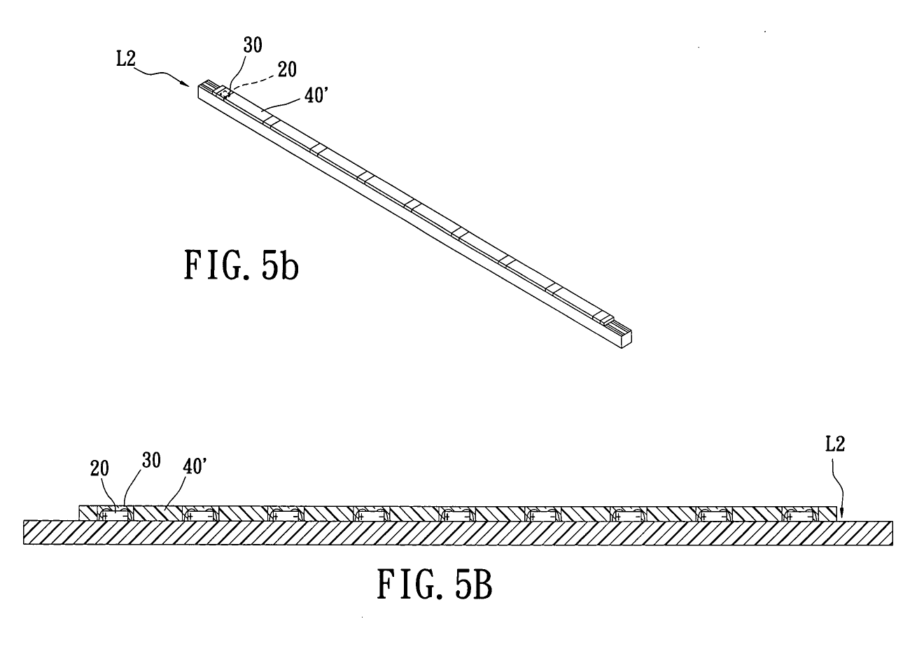

Referring to FIGS. 5, 5a to 5b, and 5A to 5B, steps S200 to S204 of the second embodiment are same as steps S100 to S104 of the first embodiment. In other words, the illustration of S200 is the same as FIGS. 2a and 2A of the first embodiment, the illustration of S202 is the same as FIGS. 2b and 2B of the first embodiment, and the illustration of S204 is the same as FIGS. 2c and 2C of the first embodiment.

After step of S204, referring to FIGS. 5, 5a and 5A, the method of the second embodiment further includes: forming a plurality of elongated opaque frame bodies 4′ on the substrate body 10 via a second mold unit M2′, and each elongated opaque frame body 4′ formed between the two elongated fluorescent bodies 3 (S206). Two of the elongated opaque frame bodies 4′ are respectively formed on the left side of the left-most elongated fluorescent body 3 and the right side of the right-most elongated fluorescent body 3. Moreover, the second mold unit M2′ is composed of a second upper mold M21′ and a second lower mold M22′ for supporting the substrate body 10. The second upper mold M21′ has a plurality of second channels M210′ corresponding to the elongated opaque frame bodies 4′.

Finally, referring to FIGS. 5, 5b, and 5B, the method of the second embodiment further includes: transversely cutting the elongated fluorescent bodies 3, the elongated opaque frame bodies 4′ and the substrate body 10 along lines each between adjacent and longitudinal LED chips 20 to form a plurality of light bars L2, and each light bar L2 having a plurality of fluorescent bodies 30 that are separated from each other and respectively covering the LED chips 20 and a plurality of opaque frame bodies 40′ that are separated from each other, and each opaque frame body 40′ is formed between the two fluorescent bodies 30 (S208).

In conclusion, when the LED chip package structure of the present invention lights up, the LED chip package structure generates a series of light-generating areas on a body unit. Because the series of light-generating areas is continuous, no dark bands are produced between two adjacent LED chips. Furthermore, because the LED chips are arranged on a substrate body via a COB (Chip On Board) method and a hot pressing method, the process of the LED chip package structure is simple and therefore reduces the required manufacturing time. Furthermore, the LED chip package structure can be applied to any type of light source such as a back light module, a decorative lamp, a lighting lamp, or a scanner.

Although the present invention has been described with reference to the preferred best molds thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An LED chip package structure applied to a backlight module, comprising:
a substrate unit;
a light-emitting unit having a plurality of LED chips electrically arranged on the substrate unit;
a package body unit having a plurality of package bodies respectively covering the LED chips; and
an opaque unit having a plurality of opaque frame bodies formed on the substrate unit, wherein two opaque frame bodies are respectively formed on two lateral sides of each package body.

2. The LED chip package structure as claimed in claim 1, wherein the substrate unit is a PCB (Printed Circuit Board), a flexible substrate, an aluminum substrate, a ceramic substrate, or a copper substrate.

3. The LED chip package structure as claimed in claim 1, wherein the substrate unit has a substrate body, and a positive trace and a negative trace respectively formed on the substrate body, and the substrate body has a metal layer and a Bakelite layer formed on the metal layer.

4. The LED chip package structure as claimed in claim 1, wherein each LED chip has a positive side and a negative side respectively and electrically connected with the positive trace and the negative trace of the substrate body, and both the positive trace and the negative trace are aluminum circuits or silver circuits.

5. The LED chip package structure as claimed in claim 1, wherein each package body is a fluorescent resin that is formed by mixing silicon and fluorescent powders or by mixing epoxy and fluorescent powders.

6. The LED chip package structure as claimed in claim 1, wherein each opaque frame body is formed and filled between two adjacent package bodies.

7. The LED chip package structure as claimed in claim 1, wherein the longitudinal width of each package body and each opaque frame body is between 0.01 mm and 0.3 mm.

8. The LED chip package structure as claimed in claim 1, further comprising: two reflective boards respectively and longitudinally disposed beside the two sides of the substrate unit, and light beams generated by the LED chips are guided along a predetermined direction by mating the two reflective boards and the opaque frame bodies.

9. The LED chip package structure as claimed in claim 8, further comprising: a light-guiding board disposed over the LED chips for receiving the light beams that have been guided by mating the two reflective boards and the opaque frame bodies.

10. A method for making an LED chip package structure applied to a backlight module, comprising:
providing a substrate unit;
electrically arranging a plurality of LED chips on the substrate unit via a matrix method to form a plurality of longitudinal LED chip rows;
longitudinally and respectively covering the longitudinal LED chip rows with a plurality of elongated package bodies; and
forming a plurality of elongated opaque frame bodies on the substrate unit, wherein the two elongated opaque frame bodies are respectively formed on two lateral sides of each elongated package body.

11. The method as claimed in claim 10, wherein the substrate unit is a PCB (Printed Circuit Board), a flexible substrate, an aluminum substrate, a ceramic substrate, or a copper substrate.

12. The method as claimed in claim 10, wherein the substrate unit has a substrate body, and a positive trace and a negative trace respectively formed on the substrate body, and the substrate body has a metal layer and a Bakelite layer formed on the metal layer.

13. The method as claimed in claim 12, wherein each LED chip has a positive side and a negative side respectively and electrically connected with the positive trace and the negative trace of the substrate body, and both the positive trace and the negative trace are aluminum circuits or silver circuits.

14. The method as claimed in claim 10, wherein the elongated package bodies are formed by a first mold unit that is composed of a first upper mold and a first lower mold for supporting the substrate unit, the first upper mold has a plurality of first channels corresponding to the longitudinal LED chip rows, and the height and the width of each first channel are the same as the height and the width of each elongated package body.

15. The method as claimed in claim 10, wherein the elongated opaque frame bodies are formed by a second mold unit that is composed of a second upper mold and a second lower mold for supporting the substrate unit, the second upper mold has a plurality of second channels corresponding to the elongated opaque frame bodies, and the height of each second channel is the same as the height of each elongated package body.

16. The method as claimed in claim 10, wherein each elongated package body is a fluorescent resin that is formed by mixing silicon and fluorescent powders or mixing epoxy and fluorescent powders.

17. The method as claimed in claim 10, further comprising: transversely cutting the elongated package bodies, the elongated opaque frame bodies and the substrate unit along lines each between adjacent and longitudinal LED chips to form a plurality of light bars, wherein each light bar has a plurality of package bodies that are separated from each other and respectively covering the LED chips and a plurality of opaque frame bodies that are separated from each other and respectively formed on two lateral sides of each package body.

18. The method as claimed in claim 10, further comprising: transversely cutting the elongated package bodies, the elongated opaque frame bodies and the substrate unit along lines each between adjacent and longitudinal LED chips to form a plurality of light bars, wherein each light bar has a plurality of package bodies that are separated from each other and respectively covering the LED chips and a plurality of opaque frame bodies that are separated from each other, and each opaque frame body is formed between two adjacent package bodies.

19. The method as claimed in claim 10, wherein the longitudinal width of each package body and each opaque frame body is between 0.01 mm and 0.3 mm.

20. The method as claimed in claim 10, further comprising: respectively and longitudinally disposing two reflective boards beside the two sides of the substrate unit, wherein light beams generated by the LED chips are guided along a predetermined direction by mating the two reflective boards and the opaque frame bodies.

21. The method as claimed in claim 20, further comprising: disposing a light-guiding board over the LED chips for receiving the light beams that have been guided by mating the two reflective boards and the opaque frame bodies.
